(19) United States
(12) Patent Application Publication
(10) Pub. No.: US 2008/0217776 A1
(43) Pub. Date: Sep. 11, 2008

(54) Process for manufacturing integrated circuits formed on a semiconductor substrate and comprising tungsten layers

(75) Inventors: Maria Santina Marangon, Merate (IT); Davide Erbetta, Trezzo Sull'Adda (IT)

Correspondence Address: GRAYBEAL, JACKSON, HALEY LLP, 155 - 108TH AVENUE NE, SUITE 350, BELLEVUE, WA, 98004-5973, US

(73) Assignee: STMICROELECTRONICS S.r.l., Agrate Brianza (IT)

(21) Appl. No.: 12/074,776

(22) Filed: Mar. 5, 2008

(30) Foreign Application Priority Data
Mar. 6, 2007 (IT) MI2007A 000446

(51) Int. Cl. H01L 21/768; H01L 23/538

(52) U.S. Cl. 257/751; 438/653; 257/E21.584; 257/E23.169

(57) ABSTRACT

An embodiment is described for manufacturing integrated circuits formed on a semiconductor substrate, which embodiment comprises forming a cobalt suicide layer on said semiconductor substrate, forming a layer comprising tungsten on said silicide layer, said cobalt suicide layer forming a barrier against the migration of the silicon atoms of said semiconductor substrate during the formation step of said layer comprising tungsten. An embodiment is also described for manufacturing contacts comprising tungsten of an integrated circuit formed on a semiconductor substrate.

### PRIORITY CLAIM

This application claims priority from Italian patent application No. M12007A 000446, filed Mar. 6, 2007 which is incorporated herein by reference.

### TECHNICAL FIELD

An embodiment of the present invention relates to a process for manufacturing integrated circuits comprising tungsten layers.

An embodiment of the invention particularly, but not exclusively, relates to a process for manufacturing contacts of an integrated circuit to be filled in with tungsten and the following description is made with reference to this field of application by way of illustration only.

### BACKGROUND

The adhesion of tungsten layers on silicon (mono or polycrystalline) substrates deposited with CVD (chemical vapor deposition) or ALD (atomic layer deposition) techniques with precursors, for examples WF6-based, may be difficult due to the chemical interactions between the precursors and the silicon substrate. The precursors may react with the silicon creating volatile compounds. Moreover, during the process of formation of the tungsten, silicon atoms may migrate towards the tungsten layer, forming suicides of the metal itself. These interactions between the silicon substrate, the tungsten layer, and the precursors used during the formation step of this tungsten layer may cause the formation of voids in the substrate itself, which thus may irremediably degrade the device.

A first known technical solution for avoiding this drawback provides for interposing, between the tungsten layer to be deposited and the silicon substrate, a protection/adhesion layer. These protection/adhesion layers typically comprise nitride layers of transition metals different from tungsten, which are generally used for coating metal gate electrodes of MOS transistors, or titanium and/or titanium nitride (TiN) layers which are generally used for coating openings or vias of the contacts of integrated circuits before filling them in with the tungsten layer.

In particular, U.S. Pat. No. 5,733,816, which is incorporated by reference, describes a method for preventing the interaction between tungsten and the silicon of a polycrystalline silicon layer whereon the tungsten layer is formed, by means of the interposition of a barrier layer which comprises nitride layers of refractory metals, which, as it is known, are obtained through a CVD (chemical vapor deposition) technique or reactive sputtering (PVD—physical vapor deposition) in a nitrogen (N2) environment.

U.S. Pat. No. 5,998,873, which is incorporated by reference, instead describes a method for forming low resistance contacts wherein each contact comprises a tungsten layer, coated by a layer of a barrier material based on refractory material such as, for example, a TiN formed through CVD, whose side walls are further coated by an adhesion metallic layer (of cobalt or nickel), while the bottom of the contact is coated by a silicide layer (of cobalt or nickel).

The barrier layer of refractory metal acts as a barrier layer between the tungsten layer and the underlying silicon, while the presence of the silicide layer lowers the contact resistance.

Although this technique may be suitable to solve the above described adhesion problems in some applications, this technique is not exempt from drawbacks. In fact having to provide a double layer which partially fills in the openings in the dielectric layer, wherein the contacts will be formed, these layers typically must be very thin for allowing a correct filling of the contact with a successive tungsten layer.

However, the formation of layers that are so thin may be difficult to be realized, in particular for the most sophisticated actual technological generations which provide contact openings of some tens of nanometers. Moreover, a barrier layer of refractory metal being too thin may not be an efficient barrier against the diffusion of the WF6, and thus against its interaction with the underlying silicon layers.

Also, the document “Silicides as contact material for DRAM Applications” by C. Fitz et al., published on Microelectronic Engineering 82 (2005), pages 460-466, which is incorporated by reference, describes the use of cobalt silicide layers coated by layers comprising titanium for reducing the contact resistances and the leakage currents in the DRAM memories.

### SUMMARY

An embodiment of the present invention is a process for realizing barrier layers between a silicon semiconductor substrate and a tungsten layer while avoiding the formation of voids at the interface between these layers, having such structural and functional features as to overcome limits and/or drawbacks still limiting the manufacturing processes realized according to the prior art.

An embodiment of the present invention comprises forming of a cobalt silicide layer on a silicon substrate prior to the formation of a tungsten layer, for example through CVD (chemical vapor deposition) or ALD (atomic layer deposition) with a WF6-based chemistry.

A further layer, for example of tungsten nitride, may be deposited prior to the deposition of the tungsten layer itself.

An embodiment of the present invention is a process for manufacturing integrated circuits formed on a semiconductor substrate, which comprises the steps of:
forming a cobalt silicide layer on said semiconductor substrate,
forming a layer comprising tungsten on said silicide layer, said cobalt silicide layer forming a barrier against the migration of the silicon atoms of said semiconductor substrate during the formation step of said layer comprising tungsten.

Another embodiment is a process for manufacturing contacts of an integrated circuit formed on a semiconductor substrate, the integrated circuit comprising at least one MOS transistor having source/drain regions separated from each other by a channel region, a gate electrode insulated from the channel region by means of an insulating layer, the process comprising the steps of:
coating said transistor with a pre-metallization insulation layer,
forming openings in said pre-metallization insulation layer for exposing portions of the source/drain regions,
forming a cobalt silicide layer on the bottom of said openings,
filling in said openings with a layer comprising tungsten, said cobalt silicide layer forming a barrier against the migration of the silicon atoms of said semiconductor substrate during the step of formation of said layer comprising tungsten.

### BRIEF DESCRIPTION OF THE DRAWINGS

Features and advantages of one or more embodiments of the invention will be apparent from the following description of an embodiment thereof given by way of indicative and non limiting example with reference to the annexed drawings.

FIGS. 1 to 5 show vertical section views of a portion of the electronic circuit during some steps of an embodiment of the invention.

### DETAILED DESCRIPTION

An embodiment of a process is described for manufacturing integrated circuits comprising tungsten layers formed on a semiconductor substrate.

The process steps and the structures described hereafter may not form a complete process flow for the manufacturing of integrated circuits.

An embodiment of the present invention may be put into practice together with the manufacturing techniques of integrated circuits currently used in the field, and only those commonly used process steps which may be beneficial for the comprehension of one or more embodiments of the present invention are included.

In particular, an embodiment of a process is described for manufacturing integrated circuits formed on a semiconductor substrate, comprising the steps of:
forming a cobalt silicide layer on the semiconductor substrate,
forming a layer comprising tungsten on the silicide layer, the cobalt silicide layer forming a barrier against the migration of the silicon atoms of the semiconductor substrate during the formation step of the layer comprising tungsten.

According to an embodiment of the invention, the cobalt silicide being a product of the reduction of the silicon, its function as a barrier layer cannot be deducted from what is known in the prior art documents referring to materials which are oxidation or nitridation products.

In particular, the used cobalt suicide layer may have a thickness comprised between approximately 10 and 100 nm, for example 30 nm.

The formation of the layer comprising tungsten may be carried out through deposition with precursors, for example WF6-based, in particular through CVD (chemical vapor deposition) or ALD (atomic layer deposition).

According to an embodiment of the invention, the cobalt silicide layer also forms a barrier against the interaction of the precursors used during the deposition step of the tungsten and the silicon substrate.

Moreover, the formation of the cobalt silicide layer comprises, for example, the steps of:
depositing a cobalt metallic layer on the silicon semiconductor substrate,
carrying out a thermal treatment for making the cobalt metallic layer react with the silicon semiconductor substrate forming a cobalt silicide layer.

For example, the formation of the cobalt metallic layer is carried out through CVD (chemical vapor deposition) or PVD (physical vapor deposition).

The cobalt metallic layer formed on the semiconductor substrate may have a thickness comprised between approximately 5 and 50 nm, for example 10 nm.

Moreover, in an embodiment of the invention, before depositing the layer comprising tungsten, a covering layer of tungsten nitride WN, for example of thickness comprised between approximately 5 and 20 nm, is formed on the cobalt silicon layer for possibly improving the adhesion of the successive W layer onto the substrate or onto the walls of the contact opening.

This tungsten nitride layer is, for example, deposited through ALD (atomic layer deposition) technology.

An embodiment of the invention for realizing contacts of integrated circuits formed on a semiconductor substrate is now described.

With reference to the FIGS., a MOS transistor 1 is described, being integrated on a silicon semiconductor substrate 2, with source/drain regions 3 separated from each other by a channel region. A gate electrode 4, for example of polysilicon, is then formed on the channel region and insulated from this latter by means of an insulating layer 5, for example of gate oxide. Nothing prevents the gate electrode 4 from comprising more polysilicon layers, to form for example a non volatile memory cell (floating gate transistor).

Spacers 6, for example of silicon nitride, are provided on the side walls of the gate electrode 4. Further insulating layers 7, for example of oxide, are provided between the spacers 6 and the gate electrodes 4 and between the spacers 6 and the semiconductor substrate 2.

A pre-metallization insulation layer 8 coats the entire transistor 1.

The pre-metallization insulation layer 8 may comprise one or more oxide layers and/or a silicon nitride layer.

With a photolithographic technique, which may involve the use of a lithographic mask and a successive etching step, openings 9 of the contacts of the pre-metallization insulation layer 8 are defined.

For example these openings 9 have a width W comprised between some tens and some hundreds of nanometers.

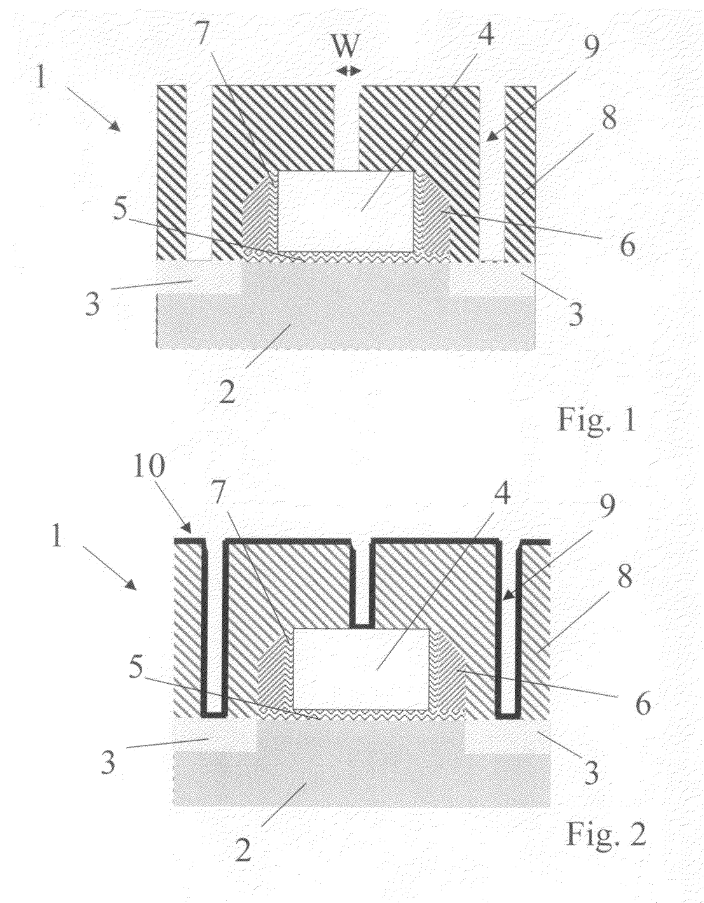

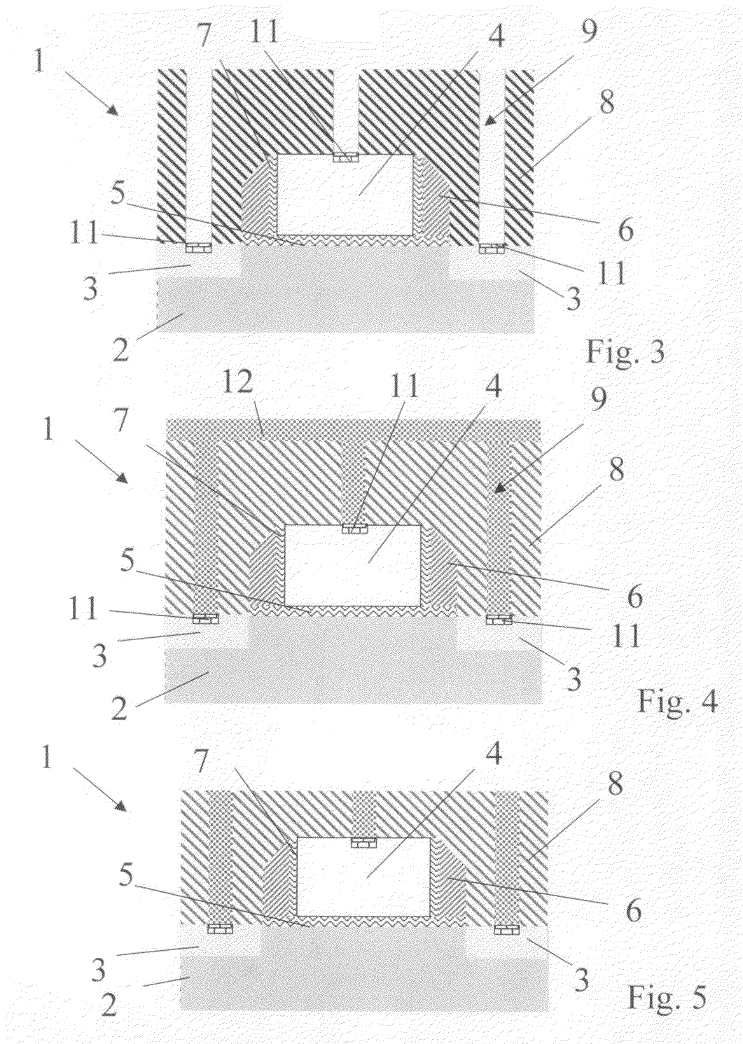

In particular, these openings 9 expose portions of the source/drain regions 3 and, of the polysilicon gate electrode 4, as shown in FIG. 1.

A cobalt metallic layer 10 is then deposited on the entire device 1, and thus also in the opening 9 of the contacts, preceded by a suitable cleaning process of the exposed surfaces of the known wet or dry type.

The cobalt metallic layer 10 may be deposited through CVD (chemical vapor deposition) or PVD (physical vapor deposition).

For example the cobalt metallic layer 10 may have a thickness comprised between approximately 5 and 50 nm, for example 10 nm.

According to an embodiment of the invention, a thermal treatment step is then carried out so that the cobalt metallic layer 10 reacts with the portions exposed by the openings 9 of the semiconductor substrate 2 and of the gate electrode 4 to form a cobalt silicide layer 11 (CoSix) on the bottom of the same openings 9.

The cobalt silicon layer 11 may have a thickness comprised between approximately 10 and 100 nm, for example 30 nm.

These formation processes of the cobalt metallic layer 10 and successive thermal treatment do not imply contra-indications if some of the openings 9 are realized on portions of the transistor 1 already provided with cobalt silicide layers. In this situation, during the thermal treatment, the cobalt metallic layer 10 will only react with the portions of silicon substrate exposed by the openings 9 without damaging the already formed layers.

The portion of the metallic layer 10 which has not reacted with the silicon substrate 2 and the polysilicon layer of the gate electrode 4 may then be removed with a chemical etching step, usually of the wet type with chemistries based on diluted ammonium hydroxide, diluted hydrochloric acid or diluted sulphuric acid.

A further thermal treatment step may be carried out so as to stabilize and complete the formation of the cobalt silicide layer 11.

In an embodiment of the invention, the cobalt silicide layer 11 may be formed prior to the pre-metallization insulation layer 8 and to the openings 9.

The openings 9 may then be filled in with a tungsten layer 12.

This filling step may be carried out through deposition with precursors, for example WF6-based, in particular through CVD (chemical vapor deposition) or ALD (atomic layer deposition), as shown in FIG. 4.

According to an embodiment of the invention, the presence of a cobalt silicide layer 11 on the bottom of the opening 9 of the contact may allow the protection of the silicon semiconductor substrate 2 and may ensure the adhesion of the tungsten layer 12 on the same.

Prior to the formation of the tungsten layer 12, a tungsten nitride layer may be deposited on the cobalt silicide layer 11 and on the pre-metallization insulation layer for improving, if necessary, the adhesion properties of the tungsten layer itself.

The manufacturing process may thus be concluded with the conventional back-end steps starting from the planarization step of the transistor 1, for example through CMP (Chemical Mechanical Polishing), and subsequent removal of the tungsten layer 12 in excess on the top of the pre-metallization insulation layer 8, as shown in FIG. 5.

In conclusion, with a process according to an embodiment of the invention, integrated circuits may be obtained whose contacts are stronger and more efficient with respect to the contacts wherein the tungsten layer is in direct contact with the exposed silicon.

Moreover with a process according to an embodiment of the invention, the filling step of the contact openings 9 may be easier since the cobalt silicon layer 11 is formed only on the bottom of the opening 9, while in the known devices the presence of a layer comprising titanium and/or titanium nitride (TiN) may remarkably reduces the section of the opening of the contact, making the several filling process steps more complex and less efficient. This aspect may be of great importance as regards memory and logic devices of the latest generation (with photo-lithographic techniques whose limit is equal to 65 nm or lower).

Although a process according to an embodiment of invention may find particular application in the formation of contacts comprising tungsten for the logic or memory CMOS processes, this process may be applied also to other manufacturing process steps of the integrated circuits, for example for the formation of metallic gate electrodes which are to be coated with a tungsten layer.

An integrated circuit (IC) that includes portions formed by and structured according to one or more embodiments of the invention may be coupled to another IC such as a controller or memory to form a system such as a computer system. The ICs may be disposed on the same or on different cites.

From the foregoing it will be appreciated that, although specific embodiments of the invention have been described herein for purposes of illustration, various modifications may be made without deviating from the spirit and scope of the invention.

What is claimed is:

1. A method for manufacturing integrated circuits formed on a semiconductor substrate, comprising:
forming a cobalt silicide layer on said semiconductor substrate,
forming a layer comprising tungsten on said silicide layer, said cobalt silicide layer forming a barrier against the migration of the silicon atoms of said semiconductor substrate during the formation step of said layer comprising tungsten.

2. The method according to claim 1, wherein said cobalt silicide layer has a thickness comprised between 10 and 100 nm, such as 30 nm.

3. The method according to claim 1, for the comprising before forming the layer comprising tungsten, a covering layer of tungsten nitride is formed on the cobalt silicide layer.

4. The method according to claim 1, wherein the formation of the layer comprising tungsten is carried out by means of deposition with precursors, the cobalt silicide layer forming a barrier against the interaction between the precursors and the silicon substrate.

5. The method according to claim 4, wherein the precursors are WF6-based.

6. The method according to claim 4, wherein said deposition is carried out through CVD (chemical vapor deposition) or ALD (atomic layer deposition).

7. The method according to claim 1, wherein the formation step of the cobalt silicide layer comprises:
depositing a cobalt metallic layer on said semiconductor substrate,
carrying out a thermal treatment for making said cobalt metallic layer react with the silicon thus forming a cobalt silicide layer.

8. The method according to claim 7, wherein the deposition of said cobalt metallic layer is carried out through CVD (chemical vapour deposition) or PVD (physical vapor deposition).

9. The method according to claim 7, wherein said cobalt metallic layer has a thickness comprised between 5 and 50 nm, such as 10 nm.

10. A method for manufacturing contacts of an integrated circuit formed on a semiconductor substrate, the integrated circuit comprising at least one MOS transistor having source/drain regions separated from each other by a channel region which is formed in said semiconductor substrate, a gate electrode insulated from the channel region by means of an insulating layer, the method comprising:
recoating said transistor with a pre-metallization insulation layer,
forming openings in said pre-metallization insulation layer for uncovering portions of said source/drain regions,
forming a cobalt silicide layer on the bottom of said openings,
filling said openings with a layer comprising tungsten, said cobalt silicide layer forming a barrier against the migration of the silicon atoms of said semiconductor substrate during the formation step of said layer comprising tungsten.

11. The method according to claim 10, wherein said cobalt silicide layer has a thickness comprised between 10 and 100 nm, such as 30 nm.

12. The method according to claim 10, wherein, before forming said cobalt silicon layer, further openings are formed in said pre-metallization insulation layer for exposing a portion of said gate electrode comprising a polysilicon layer, wherein said cobalt silicide layer is also formed on the bottom of said further openings.

13. The method according to claim 10, wherein said openings have a width comprised between some tens and some hundreds of nanometers.

14. The method according to claim 10, wherein said gate electrode comprises more polysilicon layers, to form a floating gate transistor.

15. The method according to claim 10, wherein before forming said layer comprising tungsten, a covering layer of tungsten nitride is deposited on the cobalt silicide layer and on the pre-metallization insulator.

16. The method according to claim 10, wherein the formation step of the layer comprising tungsten is carried out by means of deposition with precursors, the cobalt silicide layer forming a barrier against the interaction between precursors and the silicon substrate during the deposition step of the tungsten.

17. The method according to claim 16, wherein the precursors are WF6-based.

18. The method according to claim 16, wherein the deposition step is carried out through CVD (chemical vapor deposition) or ALD (atomic layer deposition).

19. The method according to claim 10, wherein the formation of the cobalt silicon layer comprises:
depositing a cobalt metallic layer on said pre-metallization insulation layer and on the walls and on the bottom of said openings,
carrying out a thermal treatment for making said cobalt metallic layer react with the silicon layer exposed by the opening to form a cobalt silicide layer,
removing said cobalt metallic layer which has not reacted at least from the side walls of the openings.

20. The method according to claim 19, wherein the formation of said cobalt metallic layer is carried out through CVD (chemical vapor deposition) or PVD (physical vapor deposition).

21. The method according to claim 10, wherein said cobalt silicide layer has a thickness comprised between 10 and 100 nm, such as 30 nm.

22. The method according to claim 10, wherein said cobalt silicide layer is formed prior to said pre-metallization layer at least on said portions of said source/drain regions.

23. The method according to claim 11, wherein said cobalt silicide layer is formed prior to said pre-metallization insulation layer at least on said portions of said gate electrode.

24. A method, comprising:
forming a first layer that includes cobalt silicide over a second layer of semiconductor material; and
forming a third layer that includes tungsten over the first layer.

25. The method of claim 24 wherein forming the first layer comprises:
forming a fourth layer that includes cobalt over the second layer; and
heating the fourth layer such that the cobalt in the fourth layer reacts with silicon in the second layer to form the first layer.

26. The method of claim 24 wherein forming the third layer comprises depositing tungsten over the first layer.

27. The method of claim 24 wherein forming the third layer comprises:
forming a fourth layer that includes tungsten nitride over the first layer; and
forming the third layer over the fourth layer.

28. The method of claim 24 wherein forming the first layer comprises forming the first layer directly on the second layer.

29. The method of claim 24 wherein forming the third layer comprises forming the third layer directly on the first layer.

30. An integrated circuit, comprising:
a first layer including silicon;
a second layer disposed over the first layer and including cobalt silicide; and
a third layer disposed over the second layer and including tungsten.

31. The integrated circuit of claim 30 wherein the second layer is disposed directly on the first layer.

32. The integrated circuit of claim 30 wherein the third layer is disposed directly on the second layer.

33. The integrated circuit of claim 30, further comprising a fourth layer disposed between the second and third layers and including tungsten nitride.

34. The integrated circuit of claim 30 wherein the first layer comprises a substrate.

35. A system, comprising:
a first integrated circuit, comprising,
a first layer including silicon,
a second layer disposed over the first layer and including cobalt silicide, and
a third layer disposed over the second layer and including tungsten; and
a second integrated circuit coupled to the first integrated circuit.

36. The system of claim 35 wherein the first and second integrated circuits are disposed on a same die.

37. The system of claim 35 wherein the first and second integrated circuits are disposed on respective first and second dies.

38. The system of claim 35 wherein the first integrated circuit comprises a controller.

39. The system of claim 35 wherein the second integrated circuit comprises a controller.
